(19) United States
(12) Patent Application Publication
(10) Pub. No.: US 2025/0122609 A1
(43) Pub. Date: Apr. 17, 2025

(54) Stacked Lithium-Sodium Electrochemical Battery and Fabrication Method Thereof

(71) Applicant: National Atomic Research Institute, Taoyuan (TW)

(72) Inventors: Jiun-Shen Chen, Taipei (TW); Po-Wen Chen, New Taipei (TW); Yung-Ching Liu, Hsinchu (TW)

(21) Appl. No.: 18/416,486

(22) Filed: Jan. 18, 2024

(30) Foreign Application Priority Data
Oct. 16, 2023 (TW) 112139454

(51) Int. Cl. C23C 14/34; H01M 4/04; H01M 4/1391

(52) U.S. Cl. CPC C23C 14/3464; C23C 14/083; C23C 14/3414; C23C 14/3485; H01M 4/0426; H01M 4/1391; H01M 4/381; H01M 4/40; H01M 10/0562; H01M 10/0563

(57) ABSTRACT

An electrochemical battery is fabricated with stacked layers of a lithium (Li)-sodium (Na) material. At first, on the upper and lower surfaces of a conductive substrate, a cathode, an ion transmission layer, and an anode are stacked in sequence and another conductive substrate is stacked on top of the anode. The battery is thus fabricated with bi-directionally stacking a number of the above parts. The ionic radius of Na ion is larger than that of Li ion. When Li ion is used as the conductor ion, the mobility is high as having a great energy density in favor of fast charging and discharging. When Na ion is used as the conductor ion, the Na ion has a large radius for easily obtaining a cathode featured in high capacitance. With the novel structure, the electrochemical performance of the overall battery is improved with low cost, high security, and high stability.

### TECHNICAL FIELD OF THE INVENTION

The present invention relates to lithium (Li)-sodium (Na) electrochemical battery; more particularly, to increasing capacitance through connection in parallel, where the material of cathode is characterized in stable discharge and good use-life.

### DESCRIPTION OF THE RELATED ARTS

At present, energy storage battery technology is dominated by Li-ion batteries, and the technology development is quite mature. Due to the high price of raw materials of Li battery, energy storage industries are committed to looking for other alternative materials. For example, Na-ion batteries have excellent low-temperature performance and can maintain high charging capacity from −20 degrees Celsius (° C.) to +80° C. The charging capacity of Na-ion battery is about two times higher than that of Li battery, and it also has the advantage of rapid charging and discharging.

However, because the radius of Na ion (1.02Å) is larger than that of Li ion (0.76Å), it is difficult to diffuse during the charge and discharge process, and it is easy to cause distortion of the material structure. Therefore, the main bottleneck in developing Na battery is the low energy density, which is fatal to the pursuit of endurance of energy storage currently used in mobile. The energy density of current power Li battery is about 180 to 200 watt-hours per kilogram (Wh/kg), and those under development can reach 450 Wh/kg. As compared with the energy density of a related Na battery currently available of 160 Wh/kg, it is still about 30% to 40% lower than ordinary Li battery.

Global Li resources are limited and cost high; besides, the energy density of Na battery is insufficient. Hence, the prior arts do not fulfill all user's requests on actual use.

### SUMMARY OF THE INVENTION

The main purpose of the present invention is to provide an electrochemical energy storage using a Li—Na composite, where an electrochemical battery using a composite with Li and Na ions complementing each other exerts high charging and discharging efficiency with low cost, high security, and high stability.

Another purpose of the present invention is to fabricate a cathode material through low-cost high-power impulse magnetron, where Na ions are contained within for rapid discharge without thermal annealing and, therefore, the overall process is fast.

To achieve the above purposes, the present invention is a method of fabricating a stacked Li—Na electrochemical battery, comprising steps of: (a) providing a conductive substrate, where the conductive substrate has an upper surface and a lower surface; (b) forming a cathode on each of the upper and the lower surfaces of the conductive substrate, where each the cathode comprises a topological insulator layer formed on the upper and the lower surfaces of the conductive substrate by an impulse direct current (DC) magnetron plasma source, and, on the topological insulator layer, a double-impulse DC magnetron plasma source used a target of lithium oxide (LiO₂) containing titanium (Ti) and a target of sodium carbonate (Na₂CO₃) containing Ti to form a composite cathode thin-layer through co-plating; (c) forming an ion transport layer on each the cathode, where each the ion transport layer is reactively coated by an arc plasma source with a target of metal tantalum (Ta); and, using the double-impulse DC magnetron plasma source to process reactive coating with a target of Li₂O+Ta and co-plating with a target of an alloy of lanthanum (La) and zirconium (Zr) (La+Zr=LZ), respectively, to form a structure of Ta₂O₅-doped LLZO (Li₇La₃Zr₂O₁₂); (d) forming an anode on each the ion transport layer, where each the anode uses the impulse DC magnetron plasma source with oxygen added on processing to process reactive coating with a target of ternary lithium cobalt oxide (LiCoO₂) to form a structure of LCO (LiCoO₂+Co); and (e) stacking another conductive substrate on top of the anode, where a vertically symmetrically stacked battery is thus obtained to obtain rapid discharge with Na ions. Accordingly, a novel method of fabricating a stacked Li-Na electrochemical battery is obtained.

### BRIEF DESCRIPTION OF THE DRAWINGS

The present invention will be better understood from the following detailed description of the preferred embodiment according to the present invention, taken in conjunction with the accompanying drawings, in which

FIG. 1 is the view showing the stacked lithium (Li)-sodium (Na) electrochemical battery;

FIG. 2 is the perspective view showing the co-plating device; and

FIG. 3 is the side view showing the co-plating device.

### DESCRIPTION OF THE PREFERRED EMBODIMENT

The following description of the preferred embodiment is provided to understand the features and the structures of the present invention.

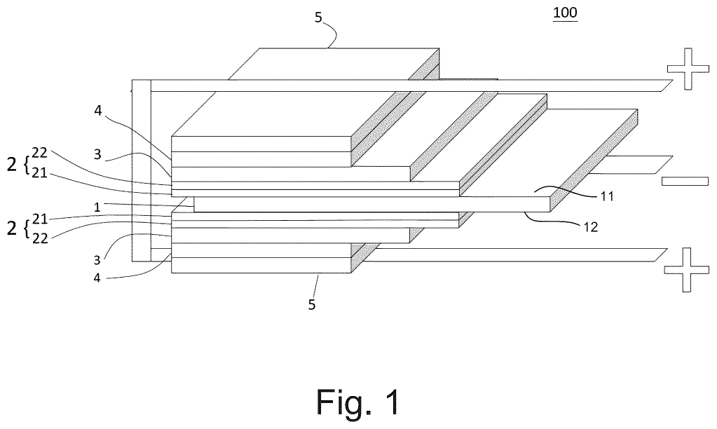

Please refer to FIG. 1 to FIG. 3, which are a view showing a stacked Li—Na electrochemical battery; a perspective view showing a co-plating device; and a side view showing the co-plating device. As shown in the figures, the present invention is a method of fabricating a stacked Li—Na electrochemical battery 100, where a cathode 2, an ion transport layer 3, and an anode 4 are sequentially stacked on an upper and a lower surfaces 11,12 of a conductive substrate 1; and another conductive substrate 5 is stacked on top of each the anode 4. Thus, a vertically symmetrically stacked battery is formed by bi-directionally stacking the above parts as shown in FIG. 1.

The cathode 2 is fabricated where a topological insulator layer 21 is formed on the upper and the lower surfaces 11,12 of the conductive substrate 1 by an impulse direct-current (DC) magnetron plasma source and, on the topological insulator layer 21, a target of lithium oxide (LiO₂) containing titanium (Ti) and a target of sodium carbonate (Na₂CO₃) containing Ti are used by a double-impulse DC magnetron plasma source to fabricate a composite cathode thin-layer 22 through co-plating.

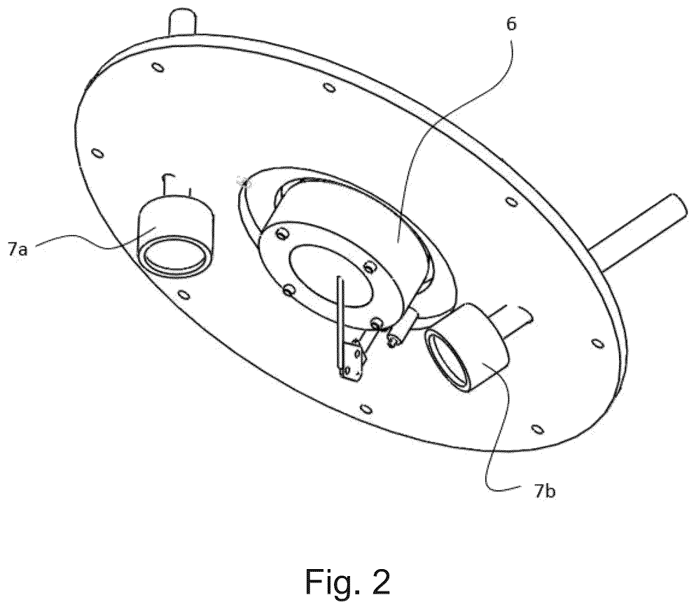

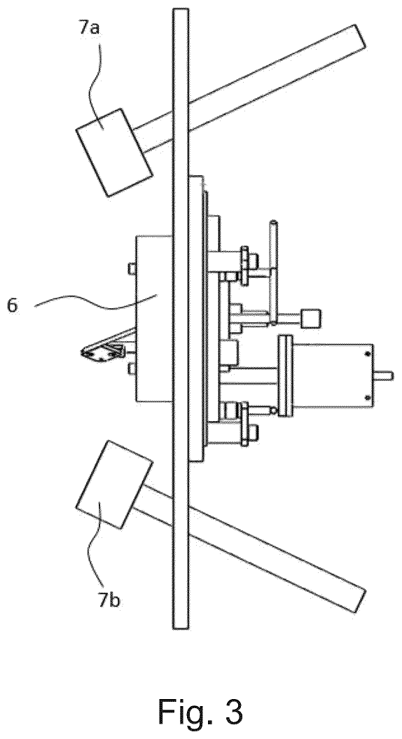

The ion transport layer 3 is an electrolyte layer, which is fabricated that an arc plasma source 6 uses a target of metal tantalum (Ta) for reactive coating and a double-impulse DC magnetron plasma source 7a, 7b is used to process reactive coating with a target of Li₂O containing tantalum (Li₂O+Ta) and co-plating with a target of an alloy of lanthanum (La) and zirconium (Zr) (La+Zr=LZ), respectively, for forming a structure of Ta₂O₅-doped LLZO (Li₇La₃Zr₂O₁₂). Therein, the perspective view and the side view of a co-plating device are shown in FIG. 2 and FIG. 3, respectively.

The anode 4 is fabricated by the impulse DC magnetron plasma source with oxygen added on processing for reactive coating with a target of ternary lithium cobalt oxide (LiCoO₂) and producing a structure of LCO (LiCoO₂+Co), which is different from LiCoO₂ made through traditional technology of radio frequency (RF) coating. Under the novel structure, the electrochemical performance of the whole battery is improved with low cost, high security, and high stability. Thus, a novel stacked Li-Na electrochemical battery 100 is obtained.

The present invention has the following characteristics:

1. Electrochemical performance improved with novel structure: The present invention provides a composite of Na and Li ions. The ionic radius of Na ion (1.02Å) is larger than that of Li ion (0.76Å). When Li ion is used as the conductor ion, the mobility is high as having a great energy density in favor of fast charging and discharging. When Na ion is used as the conductor ions, the Na ion has large radius for easily obtaining a cathode featured in high capacitance.

2. Cost reduced: The present invention has the advantages of low-cost manufacture, fast coating speed, and improved safety.

3. Fabrication time decreased: The present invention uses low-cost high-power impulse magnetron to fabricate cathode material (Ti, LTO) and local electrolyte (ion transport layer) material (Li₂O+Ta₂O₅, LaZrO) for fast fabrication.

To sum up, the present invention is a method of fabricating a stacked Li—Na electrochemical battery, where a novel vertical design of Li—Na electrochemical device is provided with a composite of Na and Li ions; as the ionic radius of Na ion is larger than that of Li ion, when Li ion is used as the conductor ion, the mobility is high as having a great energy density in favor of fast charging and discharging; when Na ion is used as the conductor ion, the Na ion has large radius for easily obtaining a negative electrode featured in high capacitance; and, with the novel structure, the electrochemical performance of the overall battery is improved with low cost, high security, and high stability.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

1. A method of fabricating a stacked lithium (Li)-sodium (Na) electrochemical battery comprising steps of:
(a) providing a first conductive substrate, wherein said first conductive substrate has an upper surface and a lower surface;
(b) sputtering a cathode on each of said upper and said lower surfaces of said first conductive substrate, wherein each said cathode comprises a topological insulator layer sputtered on said upper and said lower surfaces of said first conductive substrate by an impulse direct current (DC) magnetron first plasma source, and, on each topological insulator layer, a double-impulse DC magnetron first plasma source employs a target of lithium oxide (LiO₂) containing titanium (Ti) and a target of sodium carbonate (Na₂CO₃) containing Ti to sputter a composite cathode thin-layer through co-plating;
(c) forming an ion transport layer on each said cathode by reactively coating each composite cathode thin-layer with an arc plasma source employing a target of metal tantalum (Ta) to form Ta₂O₅; and, co-plating via a double-impulse DC magnetron second plasma source to process reactive coating with a target of lithium oxide containing tantalum (Li₂O+Ta) and with a double-impulse DC magnetron third plasma source with a target of an alloy of lanthanum (La) and zirconium (Zr) (La+Zr=LZ), respectively, to obtain a structure of Ta₂O₅-doped LLZO (Li₇La₃Zr₂O₁₂);
(d) obtaining an anode on each said ion transport layer, wherein each said anode uses an impulse DC magnetron second plasma source with oxygen added on processing to process reactive coating with a target of ternary lithium cobalt oxide (LiCoO₂) to obtain a structure of LCO (LiCoO₂+Co); and
(e) stacking a second conductive substrate on top of each anode, wherein a vertically symmetrically stacked battery is thus obtained to obtain rapid discharge with Na ions.
